(19) United States
(12) Patent Application Publication
(10) Pub. No.: US 2020/0142005 A1
(43) Pub. Date: May 7, 2020

(54) ELECTRONIC APPARATUS AND METHOD THEREOF FOR EXTENDING BATTERY LIFESPAN

(71) Applicant: Quanta Computer Inc., Taoyuan City (TW)

(72) Inventor: Wei-Ting YEN, Taoyuan City (TW)

(21) Appl. No.: 16/299,209

(22) Filed: Mar. 12, 2019

(30) Foreign Application Priority Data
Nov. 6, 2018 (TW) 107139236

(51) Int. Cl. G01R 31/382; H01M 10/48; H01M 10/44; G01R 31/36; H01M 10/42

(52) U.S. Cl. CPC G01R 31/382; H01M 10/482; H01M 2010/4271; G01R 31/3646; H01M 10/425; H01M 10/441

(57) ABSTRACT

An electronic apparatus includes a battery module, a measurement unit and a processing unit. The battery module provides a power signal. The measurement unit coupled to the battery module measures the power signal of the battery module to generate a measurement signal. The processing unit coupled to the battery module and the measurement unit receives the measurement signal to calculate and obtain a power capacity of the battery module, and generates a first controlling signal according to the power capacity of the battery module and the monitoring time, such that the battery module enters a shutdown mode.

### CROSS REFERENCE TO RELATED APPLICATIONS

This application claims priority of Taiwan Patent Application No. 107139236, filed on Nov. 6, 2018, the entirety of which is incorporated by reference herein.

### BACKGROUND OF THE INVENTION

### Field of the Invention

The present invention relates to an electronic device, and in particular it relates to an electronic device and a method thereof for extending a battery's lifespan.

### Description of the Related Art

With the progress that is being made in technology, mobile devices have become indispensable. A battery is an indispensable part of a mobile device. However, batteries are often stored for too long or not used for a long time, and the battery has over-discharged or cannot be charged after over-discharge. Therefore, consumers may complain that the battery has broken after only having used it a few times, or that the battery has broken after being in storage for too long.

A battery is constructed by chemical compositions, and a battery may experience self-discharge even when the battery is in a placement state It is worrying that after the battery has not been used for a long time, the battery has been over-discharged for a long time, and there is no mechanism for the battery to be recharged to cause copper precipitation of the battery, such that the battery is broken. After the copper precipitation of the battery, the entire circuit board of the system terminal of the mobile device may become corroded, limiting the lifespan of the battery. Therefore, how to increase the lifespan of a battery has become a focus for technical improvements by various manufacturers.

### BRIEF SUMMARY OF THE INVENTION

The present invention is to provide an electronic device and a method thereof for extending a battery's lifespan, thereby effectively reducing power consumption of the battery and increasing the lifespan of the battery.

The present invention provides an electronic device, which includes a battery module, a measurement unit and a processing unit. The battery module provides a power signal. The measurement unit is coupled to the battery module and measures the power signal of the battery module to generate a measurement signal. The processing unit is coupled to the battery module and the measurement unit, receives the measurement signal to calculate and obtain a power capacity of the battery module, and generates a first controlling signal according to the power capacity of the battery module and a monitoring time, such that the battery module enters a shutdown mode.

The present invention provides a method for extending a battery lifespan of an electronic device, which includes the following steps. A power signal of a battery module is measured to generate a measurement signal. The measurement signal is received to calculate and obtain a power capacity of the battery module. a first controlling signal is generated according to the power capacity of the battery module and a monitoring time, such that the battery module enters a shutdown mode.

According to the electronic device and the method thereof for extending the battery lifespan, the measurement unit measures the power signal of the battery module to generate the measurement signal, and the processing unit calculates and obtains the power capacity of the battery module according to the measurement signal and generates the first controlling signal according to the power capacity of the battery module and the monitoring time, such that the battery module enters the shutdown mode. Therefore, the power consumption of the battery is effectively reduced and the lifespan of the battery module is increased.

### BRIEF DESCRIPTION OF THE DRAWINGS

The present invention can be more fully understood by reading the subsequent detailed description and examples with references made to the accompanying drawings, wherein:

FIG. 1 shows a schematic view of an electronic device according to an embodiment of the present invention;

FIG. 2 shows a schematic view of a battery module according to an embodiment of the present invention;

FIG. 3 shows a waveform diagram of a power capacity of the battery module and the number of days according to an embodiment of the present invention;

FIG. 4 is a flowchart of a method for extending a battery lifespan of an electronic device according to an embodiment of the present invention;

FIG. 5 is a flowchart of a method for extending a battery lifespan of an electronic device according to another embodiment of the present invention;

FIG. 6 is a flowchart of a method for extending a battery lifespan of an electronic device according to another embodiment of the present invention; and

FIG. 7 is a flowchart of a method for extending a battery lifespan of an electronic device according to another embodiment of the present invention.

### DETAILED DESCRIPTION OF THE INVENTION

In each of the following embodiments, the same reference number represents the same or similar element or component.

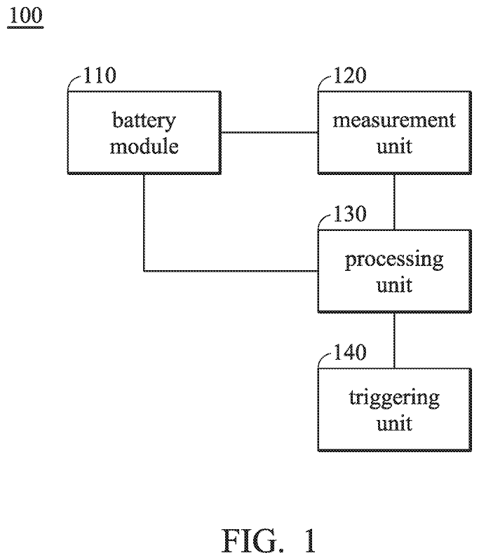

FIG. 1 shows a schematic view of an electronic device according to an embodiment of the present invention. Please refer to FIG. 1, the electronic device 100 includes a battery module 110, a measurement unit 120 and a processing unit 130.

The battery module 110 provides a power signal for the electronic device 100, such that the electronic device 100 may operate in a normal operation mode or a sleep mode. The measurement unit 120 is coupled to the battery module 110 and measures the power signal of the battery module 110 to generate a measurement signal.

The processing unit 130 is coupled to the battery module 110 and the measurement unit 120. The processing unit 130 receives the measurement signal to calculate and obtain a power capacity of the battery module 110. The processing unit 130 generates a first controlling signal according to the power capacity of the battery module 110 and a monitoring time, such that the battery module 110 enters a shutdown mode. After the battery module 110 enters a shutdown mode, the battery module 110 has only its own self-discharge. Therefore, the power consumption of the battery module 110 is effectively reduced and the lifespan of the battery module 110 is increased.

In the embodiment, the processing unit 130 further compares the power capacity of the battery module 110 with a first predetermined value and the monitoring time with a predetermined time. That is, when the processing unit 130 receives the measurement signal, the processing unit 130 may calculate and obtain the power capacity of the battery module 110. Then, the processing unit 130 compares the power capacity of the battery module 110 with the first predetermined value, for example, determines whether the power capacity of the battery module 110 is less than the first predetermined value, so as to determine a power consumption state of the battery module 110.

In addition, when the processing unit 130 starts to receive the measurement signal of the measurement unit 120, the processing unit 130 may count a time and designate the time as a monitoring time. Then, the processing unit 130 compares the monitoring time with the predetermined time, for example, determines whether the monitoring time is greater than or equal to the predetermined time, as a basis for whether or not the mode of the battery module 110 needs to be adjusted.

In the embodiment, the first predetermined value is, for example, 30% of the total power (100%) of the battery module 110, and the predetermined time is, for example, 30 days. The above setting of the first predetermined value and the predetermined time is one exemplary embodiment of the present invention, but not intended to limit the present invention. The user may adjust the setting of the first predetermined value and the predetermined time according to the requirement thereof, and the adjustments belong to the protection scope of the present invention.

When the power capacity of the battery module 110 is less than the first predetermined value and the predetermined time is greater than or equal to the predetermined time, it indicates that the power capacity of the battery module 110 is already less than 30% of the total power of the battery module 110 and the monitoring time already exceeds 30 days. The processing unit 130 may generate the first controlling signal to the battery module 110, such that the battery module 110 enters the shutdown mode.

Since the battery module 110 switches to the shutdown mode from the normal operation mode, the battery module does not supply the power to the electronic device 100 and the battery module 110 has only its own self-discharge (for example, about 5 uA). Therefore, the power consumption of the battery module 110 may be effectively reduced and the lifespan of the battery module 110 may be increased.

In another aspect, when the power capacity of the battery module 110 is not less than the first predetermined value and the monitoring time is not greater than or equal to the predetermined time, it indicates that the power capacity of the battery module 110 is not less than 30% of the total power of the battery module 110 and the monitoring time does not exceed 30 days. Then, the processing unit 130 does not generate the first controlling signal to the battery module 110, such that the battery module 110 maintains the normal operation mode.

That is, the battery module 110 still provides the power to the electronic device 100. When the electronic device 100 is in the normal operation mode, the battery module 110 provides, for example, power signal with about 600 uA to the electronic device 100. When the electronic device 100 is in the sleep mode or is turned off, the battery module 110 provides, for example, the power signal with about 200 uA to the electronic device 100.

In addition, when the battery module 110 enters the shutdown mode, the processing unit 130 further compares the power capacity of the battery module 110 with a second predetermined value. That is, after the processing unit 130 generates the first controlling signal, the processing unit 130 still continues to monitor the power capacity of the battery module 110. Then, the processing unit 130 compares the power capacity of the battery module 110 with the second predetermined value, for example determines whether the power capacity of battery module 110 is less than the second predetermined value, so as to determine whether the battery module 110 is about to be out of power or has been over-discharged.

In the embodiment, the second predetermined value is less than the first predetermined value (30%), and the second predetermined value is, for example, 5% of the total power capacity of the battery module 110. The above setting of the second predetermined value is one exemplary embodiment of the present invention, but not intended to limit the present invention. The user may adjust the setting of the second predetermined value and according to the requirement thereof, and the adjustments belong to the protection scope of the present invention.

When the power capacity of the battery module 110 is less than the second predetermined value, it indicates that the battery module 110 is about to be out of power or has been over-discharged. Then, the processing unit 130 generates an alarm signal. The alarm signal is further transmitted to an alarm unit (not shown), such that the alarm unit may transmit the alarm signal. Therefore, the use may know the state of the battery module 110, i.e., the battery module 110 is about to be out of power or has been over-discharged, such that the user may perform the corresponding process for the battery module 110.

In the embodiment, the above alarm unit is, for example, a buzzer or a speaker. The alarm unit may transmit the alarm signal in a sound manner, such that the user may know the state of the battery module 110. Alternatively, the alarm unit is, for example, a light emitting diode. The alarm unit may transmit the alarm signal in a light-emitting manner (such as flicker), such that the user may know the state of the battery module 110.

When the power capacity of the battery module 110 is not less than the second predetermined value, it indicates the battery module 110 is not about to be out of power or have not been over-discharged. The processing unit 130 continues to receive the measurement signal provided by the measurement module 120 and compare the power capacity of the battery module 110 with the second predetermined value until when the power capacity of the battery module 110 is less than the second predetermined value, the processing unit 130 generates the alarm signal.

Furthermore, after the battery module 110 enters the shutdown mode, the processing unit 130 further determines whether a boot signal or an external power signal is received as a basis for whether or not the shutdown mode of the battery module 110 needs to be released. The boot signal is, for example, generated by the power button (not shown) of the electronic device 100 pressed by the user. The external power signal is, for example, generated by connecting the electronic device 100 to an external power (not shown, and such as an electricity) by the user.

When the processing unit 130 determines that the boot signal or the external power signal is received, it indicates that the electronic device 100 needs to be activated or the battery module 110 may be charged. Then, the processing unit 130 generates the second controlling signal, such that the battery releases the shutdown mode to enter the normal operation mode. Therefore, the battery module 110 may provide the power signal (such as about 600 uA or about 200 uA) or the battery module 110 may be charged by the external power.

When the processing unit 130 determines that the boot signal or the external power signal is not received, the processing unit 130 continues to determine whether the boot signal or the external power signal is received until when the processing unit 130 receives the boot signal or the external power signal, the processing unit 130 generates the second controlling signal, such that the battery module 110 releases the shutdown mode to enter the normal operation mode.

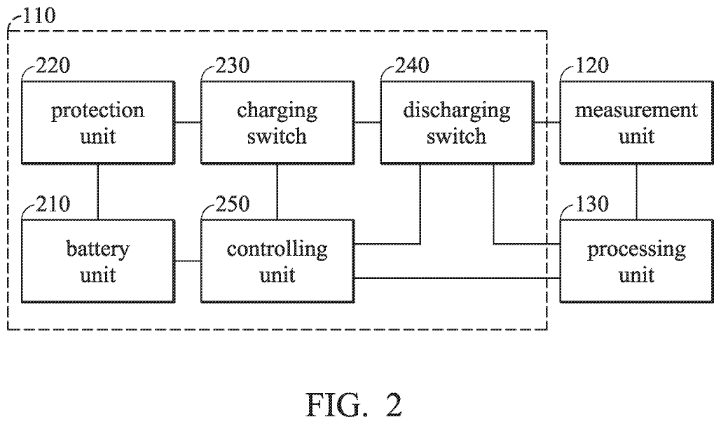

In the embodiment, the battery module 110 includes a battery unit 210, a protection unit 220, a charging switch 230, a discharging switch 240 and a controlling unit 250, as shown in FIG. 2. The battery unit 210 provides the power signal. The protection unit 220 is coupled to the battery unit 210. The protection unit 220 is, for example, a fuse. The charging switch 230 is coupled to the protection unit 220. The discharging switch 240 is coupled to the charging switch 230, the measurement unit 120 and the processing unit 130.

The controlling unit 250 is coupled to the battery unit 210, the charging switch 230, the discharging switch 240 and the processing unit 130. The controlling unit 250 receives the first controlling signal and the second controlling signal and controls the operations of the charging switch 230 and the discharging switch 240 according to the first controlling signal and the second controlling signal, such that the battery module 110 enters the shutdown mode or the normal operation mode.

For example, when the controlling unit 250 receives the first controlling signal generated by the processing unit 130, the controlling unit 250 may control the charging switch 230 and discharging switch 240 to be turned off according to the first controlling signal, such that the battery module 110 enters the shutdown mode. Then, the battery module 110 only has self-discharge of the battery unit 210. Therefore, the power consumption of the battery module 110 may be effectively reduced and the lifespan of the battery module 110 is increased.

When the controlling unit 250 does not receive the first controlling signal generated by the processing unit 130, the battery module 110 maintains the normal operation mode. The controlling unit 250 may control the charging switch 230 and the discharging switch 240 to be turned on or off according to the operation of the electronic device 100.

For example, when the operation state of the electronic device 100 is the normal operation mode, the controlling unit 250 may control the charging switch 230 and the discharging switch 240 to be turned on, such that the battery unit 210 may provide the power signal (such as about 600 uA) to the electronic device 100 or may be charged by the external power signal. When the operation state of the electronic device 100 is the sleep mode, the controlling unit 250 may control the charging switch 230 to be turned off and the discharging switch 240 to be turned on, such that the battery unit 210 may provide the power signal (such as about 200 uA) to the electronic device 100.

When the controlling unit 250 receives the second controlling signal generated by the processing unit 130, the controlling unit 250 may control the charging switch 230 and discharging switch 240 to be turned on according to the second controlling signal, such that the battery unit 210 may provide the power signal (such as about 600 uA) to the electronic device 100 or may be charged by the external power signal.

Furthermore, the electronic device 100 further includes a triggering unit 140. The triggering unit 140 is coupled to the processing unit 130 and provides a triggering signal to the processing unit 130. In the embodiment, the triggering unit 140 is, for example, a button. That is, the user may press the triggering unit 140 to generate the triggering signal. Then, when the processing unit 130 receives the triggering signal, the processing unit 130 may generate the first controlling signal according to the triggering signal, such that the battery module 110 enters the shutdown mode.

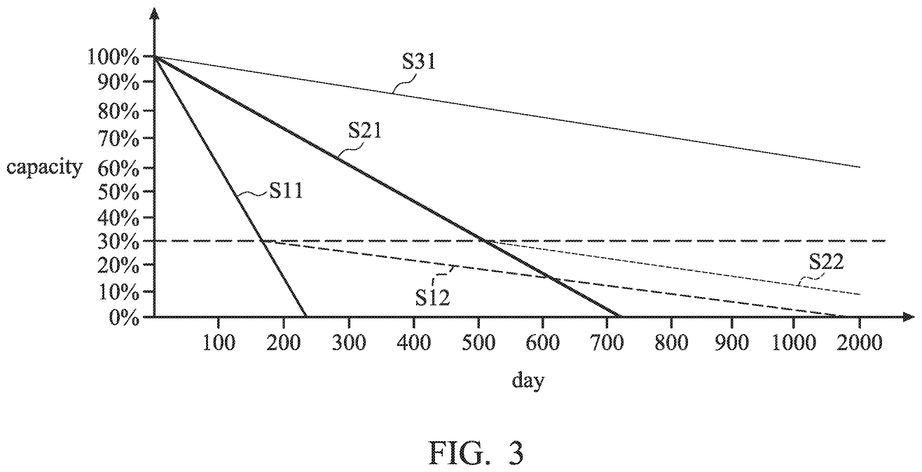

FIG. 3 shows a waveform diagram of a power capacity of the battery module and the number of days according to an embodiment of the present invention. In FIG. 3, a curve S11 indicates a curve of the power consumption of the battery module 110 in the normal operation mode of the electronic device 100. A curve S21 indicates a curve of the power consumption of the battery module 110 in the sleep mode of the electronic device 100. Curves S31, S11 and S11 respectively indicate a curve of the power consumption when the battery module 110 enters the shutdown mode.

It can be seen from FIG. 3, when the battery module 110 is in the normal operation mode of the electronic device 100, the power consumption of the battery module 110 is the curve S11. Then, after the processing unit 130 generates the first controlling signal to control the battery module 110 to enter the shutdown mode, the power consumption of the battery module 110 changes to the curve S12 from the curve S11. In addition, when the battery module 110 is in the sleep mode of the electronic device 100, the power consumption of the battery module 110 is the curve S21. Then, after the processing unit 130 generates the first controlling signal to control the battery module 110 to enter the shutdown mode, the power consumption of the battery module 110 changes to the curve S22 from the curve S21.

It can be seen from the above content, according to the operation of the above embodiment of the present invention, i.e., the battery module 110 enters the shutdown mode according to the triggering signal or the power capacity of the battery module 110 and the monitoring time, the power consumption of the battery module 110 changes to the curve S12 or curve S22. Therefore, the power consumption of the battery module 110 may be effectively reduced and the lifespan of the battery module 110 is increased.

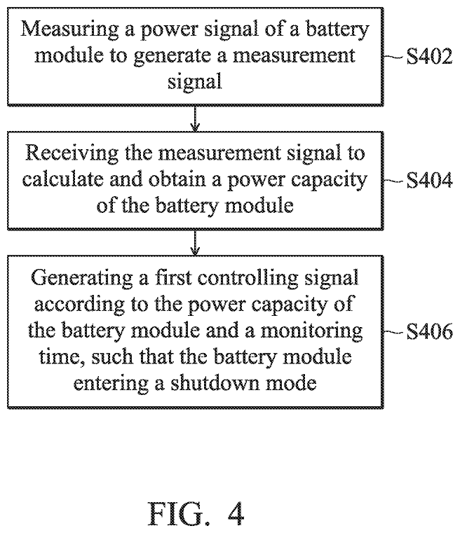

According to the above-mentioned description, the above embodiments may combine a method for extending a battery lifespan of an electronic device. FIG. 4 is a flowchart of a method for extending a battery lifespan of an electronic device according to an embodiment of the present invention. In step S402, the method involves measuring a power signal of a battery module to generate a measurement signal. In step S404, the method involves receiving the measurement signal to calculate and obtain a power capacity of the battery module. In step S406, the method involves generating a first controlling signal according to the power capacity of the battery module and a monitoring time, such that the battery module entering a shutdown mode.

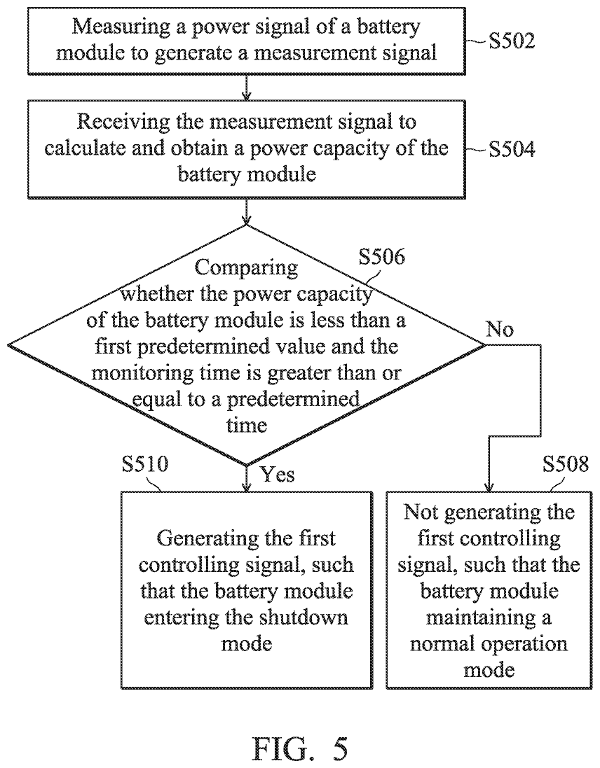

FIG. 5 is a flowchart of a method for extending a battery lifespan of an electronic device according to another embodiment of the present invention. In step S502, the method involves measuring a power signal of a battery module to generate a measurement signal. In step S504, the method involves receiving the measurement signal to calculate and obtain a power capacity of the battery module. In step S506, the method involves comparing whether the power capacity of the battery module is less than a first predetermined value and the monitoring time is greater than or equal to a predetermined time.

When the power capacity of the battery module is not less than the first predetermined value and the monitoring time is not greater than or equal to the predetermined time, the method goes to step S508. In the step S508, the method involves not generating the first controlling signal, such that the battery module maintaining a normal operation mode. When the power capacity of the battery module is less than the first predetermined value and the monitoring time is greater than or equal to the predetermined time, the method goes to step S510. In the step S510, the method involves generating the first controlling signal, such that the battery module entering the shutdown mode.

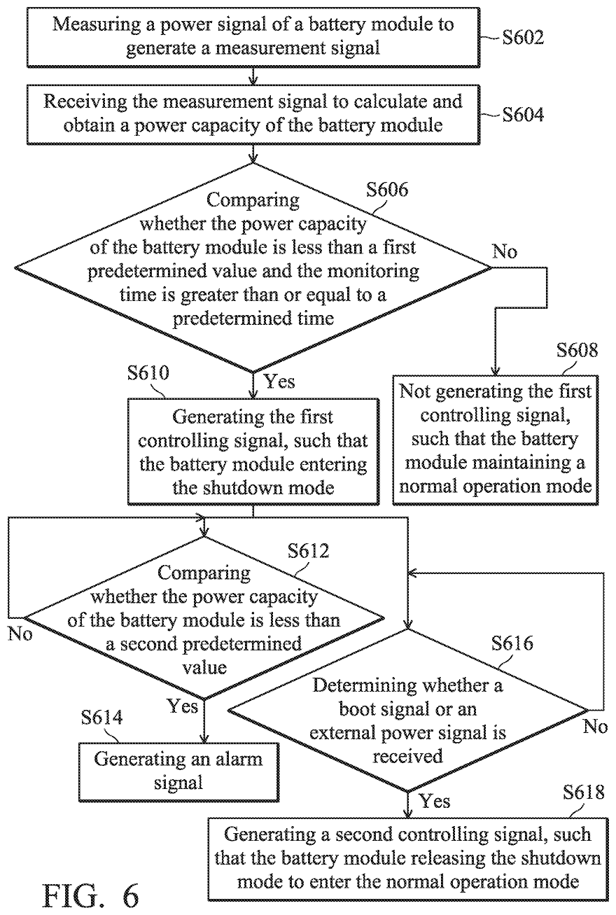

FIG. 6 is a flowchart of a method for extending a battery lifespan of an electronic device according to another embodiment of the present invention. In step S602, the method involves measuring a power signal of a battery module to generate a measurement signal. In step S604, the method involves receiving the measurement signal to calculate and obtain a power capacity of the battery module. In step S606, the method involves comparing whether the power capacity of the battery module is less than a first predetermined value and the monitoring time is greater than or equal to a predetermined time.

When the power capacity of the battery module is not less than the first predetermined value and the monitoring time is not greater than or equal to the predetermined time, the method goes to step S608. In the step S608, the method involves not generating the first controlling signal, such that the battery module maintaining a normal operation mode. When the power capacity of the battery module is less than the first predetermined value and the monitoring time is greater than or equal to the predetermined time, the method goes to step S610. In the step S610, the method involves generating the first controlling signal, such that the battery module entering the shutdown mode.

In step S612, the method involves comparing whether the power capacity of the battery module is less than a second predetermined value, wherein the second predetermined value is less than the first predetermined value. When the power capacity of the battery module is less than the second predetermined value, the method goes to step S614. In the step S614, the method involves generating an alarm signal. When the power capacity of the battery module is not less than the second predetermined value, the method goes to the step S612, such that the method continues to compare the power capacity of the battery module with the second predetermined value.

In step S616, the method involves determining whether a boot signal or an external power signal is received. When determining that the boot signal or the external power signal is received, the method goes to step S618. In the step S618, the method involves generating a second controlling signal, such that the battery module releasing the shutdown mode to enter the normal operation mode. When determining that the boot signal or the external power signal is not received, the method goes to the step S616 and the method continues to determine whether the boot signal or the external power signal is received.

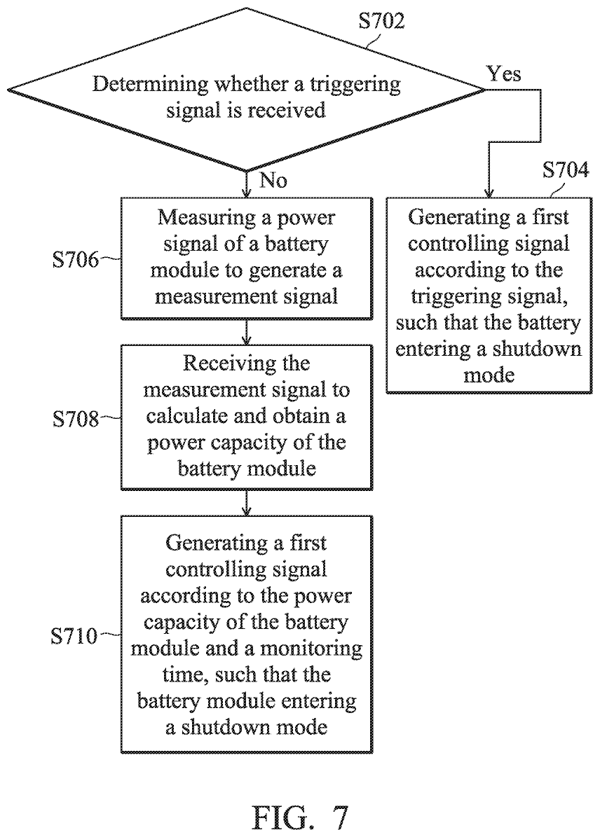

FIG. 7 is a flowchart of a method for extending a battery lifespan of an electronic device according to another embodiment of the present invention. In step 702, the method involves determining whether a triggering signal is received. When determining that the triggering signal is received, the method goes to step S704. In the step S704, the method involves generating a first controlling signal according to the triggering signal, such that the battery entering a shutdown mode.

When determining that the triggering signal is not received, the method goes to step S706. In the step S706, the method involves measuring a power signal of a battery module to generate a measurement signal. In step S708, the method involves receiving the measurement signal to calculate and obtain a power capacity of the battery module. In step S710, the method involves generating a first controlling signal according to the power capacity of the battery module and a monitoring time, such that the battery module entering a shutdown mode.

In summary, according to the electronic device and the method thereof for extending the battery lifespan, the measurement unit measures the power signal of the battery module to generate the measurement signal, and the processing unit calculates and obtains the power capacity of the battery module according to the measurement signal and generates the first controlling signal according to the power capacity of the battery module and the monitoring time, such that the battery module enters the shutdown mode. In addition, the processing unit may also generate the first signal according to the triggering signal generated the triggering unit, such that the battery module enters the shutdown mode. Therefore, the power consumption of the battery is effectively reduced and the lifespan of the battery module is increased.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electronic device, comprising:
a battery module, providing a power signal;
a measurement unit, coupled to the battery module, measuring the power signal of the battery module to generate a measurement signal; and
a processing unit, coupled to the battery module and the measurement unit, receiving the measurement signal to calculate and obtain a power capacity of the battery module, and generating a first controlling signal according to the power capacity of the battery module and a monitoring time, such that the battery module entering a shutdown mode.

2. The electronic device as claimed in claim 1, wherein the processing unit further compares the power capacity of the battery module with a first predetermined value and the monitoring time with a predetermined time, when the power capacity of the battery module is less than the first predetermined value and the monitoring time is greater than or equal to the predetermined time, the processing unit generates the first controlling signal, such that the battery module enters the shutdown mode, and when the power capacity of the battery module is not less than the first predetermined value and the monitoring time is not greater than or equal to the predetermined time, the processing unit does not generate the first controlling signal, such that the battery module maintains a normal operation mode.

3. The electronic device as claimed in claim 2, wherein after the battery module enters the shutdown mode, the processing unit further compares the power capacity of the battery module with a second predetermined value, when the power capacity of the battery module is less than the second predetermined value, the processing unit generates an alarm signal, and when the power capacity of the battery module is not less than the second predetermined value, the processing unit continues to compare the power capacity of the battery module with the second predetermined value, wherein the second predetermined value is less than the first predetermined value.

4. The electronic device as claimed in claim 2, wherein after the battery module enters the shutdown mode, the processing unit further determines whether a boot signal or an external power signal is received, when the processing unit determines that the boot signal or the external power signal is received, the processing unit generates a second controlling signal, such that the battery module releases the shutdown mode to enter the normal operation mode, and when the processing unit determines that the boot signal or the external power signal is not received, the processing unit continues to determine whether the boot signal or the external power signal is received.

5. The electronic device as claimed in claim 4, wherein the battery module comprises:
a battery unit, providing the power signal;
a protection unit, coupled to the battery unit;
a charging switch, coupled to the protection unit;
a discharging switch, coupled to the charging switch, the measurement unit and the processing unit; and
a controlling unit, coupled to the battery unit, the charging switch, the charging switch and the processing unit, receiving the first controlling signal and the second controlling signal, and controlling operations of the charging switch and the discharging switch according to the first controlling signal and the second controlling signal, such that the battery entering the shutdown mode or the normal operation mode.

6. The electronic device as claimed in claim 1, further comprising:
a triggering unit, coupled to the processing unit, providing a triggering signal to the processing unit;
wherein the processing unit further generates the first controlling signal according to the triggering signal, such that the battery module enters the shutdown mode.

7. A method for extending a battery lifespan of an electronic device, comprising:
measuring a power signal of a battery module to generate a measurement signal;
receiving the measurement signal to calculate and obtain a power capacity of the battery module; and
generating a first controlling signal according to the power capacity of the battery module and a monitoring time, such that the battery module entering a shutdown mode.

8. The method for extending the battery lifespan of the electronic device as claimed in claim 7, wherein the step of generating the first controlling signal according to the power capacity of the battery module and the monitoring time, such that the battery module entering the shutdown mode comprises:
comparing the power capacity of the battery module with a first predetermined value and the monitoring time with a predetermined time;
when the power capacity of the battery module is less than the first predetermined value and the monitoring time is greater than or equal to the predetermined time, generating the first controlling signal, such that the battery module entering the shutdown mode; and
when the power capacity of the battery module is not less than the first predetermined value and the monitoring time is not greater than or equal to the predetermined time, not generating the first controlling signal, such that the battery module maintaining a normal operation mode.

9. The method for extending the battery lifespan of the electronic device as claimed in claim 8, wherein the method after step of generating the first controlling signal, such that the battery module enters the shutdown mode further comprises:
comparing the power capacity of the battery module with a second predetermined value, wherein the second predetermined value is less than the first predetermined value;
when the power capacity of the battery module is less than the second predetermined value, generating an alarm signal; and
when the power capacity of the battery module is not less than the second predetermined value, returning to the step of comparing the power capacity of the battery module with a second predetermined value.

10. The method for extending the battery lifespan of the electronic device as claimed in claim 8, wherein the method after the step of generating the first controlling signal, such that the battery module enters the shutdown mode further comprises:
determining whether a boot signal or an external power signal is received;
when determining that the boot signal or the external power signal is received, generating a second controlling signal, such that the battery module releasing the shutdown mode to enter the normal operation mode; and
when determining that the boot signal or the external power signal is not received, returning to the step of determining whether a boot signal or an external power signal is received.
